(19) United States
(12) Patent Application Publication
(10) Pub. No.: US 2017/0299114 A1
(43) Pub. Date: Oct. 19, 2017

(54) WALL-HANG APPARATUS AND DISPLAY DEVICE

(71) Applicants: LE HOLDINGS (BEIJING) CO., LTD., Beijing (CN); LE SHI ZHI XIN ELECTRONIC TECHNOLOGY (TIAN JIN) LIMITED, Tianjin (CN)

(72) Inventors: Dacheng MEN, Tianjin (CN); Shiming QING, Tianjin (CN); Feng SUN, Tianjin (CN)

(21) Appl. No.: 15/232,476

(22) Filed: Aug. 9, 2016

Related U.S. Application Data
(63) Continuation of application No. PCT/CN2016/081455, filed on May 9, 2016.

(30) Foreign Application Priority Data
Apr. 14, 2016 (CN) 201610232625.X

(51) Int. Cl. F16M 13/02; A47B 97/00; F16M 11/08; H05K 5/02; H05K 5/00

(52) U.S. Cl. CPC F16M 13/02; H05K 5/0217; H05K 5/0017; A47B 97/00; F16M 11/08; A47B 2097/005

(57) ABSTRACT

The present disclosure provides a wall-hang apparatus and a display device. The wall-hang apparatus includes a base, a wall plate, and at least one bracket, wherein the base is fixedly connected with a wall, the wall plate is hinged with the base through a swivel, the swivel is vertically projected onto the wall, and the at least one bracket is fixedly connected with a backside of a display device body and is hitched to the wall plate. After the display device is hung on the wall through the wall-hang apparatus according to the present disclosure, the display device body can be swiveled leftward and rightward around the swivel to thereby provide an operating user with a larger room of conveniently inserting a line while lowering the risk of the display device body falling out of the wall-hang apparatus.

### CROSS REFERENCE TO RELATED APPLICATIONS

This application is a continuation of International Application No. PCT/CN2016/081455, filed on May 09, 2016, which is based upon and claims priority to Chinese Patent Application No. 201610232625.X, filed on Apr. 14, 2016 the entire contents of which are incorporated herein by reference.

### TECHNICAL FIELD

The present disclosure relates to the field of installing a display device, and particularly to a wall-hang apparatus and a display device.

### BACKGROUND

A wall-hang bracket which is an accessory device through which a tablet TV set is attached to a wall has been widely applied at home, in an office, a meeting room, an exhibition hall, a hotel, an airport, a railway station, a hospital, a bus stop, a shopping mall, and other places. The common bracket on which the TV set is hung generally includes a wall plate installed on the wall, and two brackets installed on the backside of the TV set, so that the TV set can be hung on the wall plate through hooks on the two brackets.

The inventors have identified during making the application at least the following problems in the prior art: after the TV set is hung on the wall through the existing wall-hang bracket, there is such a small space between the TV set and the wall that it may not be operationally convenient for the user to insert a line, and if the user exerts too much force, then the TV set may accidentally fall down from the wall-hang bracket.

### SUMMARY

The present disclosure provides a wall-hang apparatus and a display device for the convenience of inserting a line on the display device so as to improve the security and the reliability of the display device hung on a wall.

In one aspect, embodiments of the present disclosure provides a wall-hang apparatus including a base, a wall plate, and at least one bracket, wherein the base is fixedly connected with a wall, the wall plate is hinged with the base through a swivel, the swivel is vertically projected onto the wall, and the at least one bracket is fixedly connected with a backside of a display device body and is hitched to the wall plate.

In another aspect, embodiments of the present disclosure further provides a display device including a display device body, and a wall-hang apparatus including a base, a wall plate, and at least one bracket, wherein the base is fixedly connected with a wall, the wall plate is hinged with the base through a swivel, the swivel is vertically projected onto the wall, and the at least one bracket is fixedly connected with a backside of a display device body and is hitched to the wall plate. After the display device is attached to the wall, it will be convenient for a user to insert a line, and the display device can be hung on the wall securely and reliably.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a schematic perspective view of a wall-hang apparatus according to an embodiment of the present disclosure;

FIG. 2 is a backside view of the wall-hang apparatus according to the embodiment of the present disclosure;

FIG. 3 is a cross sectional view along A-A in FIG. 2; and

FIG. 4 is a side view of the display device being attached to a wall.

### REFERENCE NUMERALS

1-Base
2-Wall plate
3-Bracket
4-Swivel
5-Buffer pad
6-Elastic damper bushing
7-Upper dust-proof cover
8-Lower dust-proof cover
9-Locking bolt
10-hook
11-Bolt installation base
100-Display device body
200-Wall
300-Wall-hang apparatus

### DETAILED DESCRIPTION

In order to make the objects, technical solutions, and advantages of the disclosure more apparent, the technical solutions in the embodiments of the disclosure will be described below clearly and fully with reference to the drawings in the embodiments of the disclosure, and apparently the embodiments as described are merely a part but not all of the embodiments of the disclosure. All the other embodiments which can occur to those ordinarily skilled in the art from the embodiments here of the disclosure without any inventive effort shall fall into the scope of the disclosure as claimed.

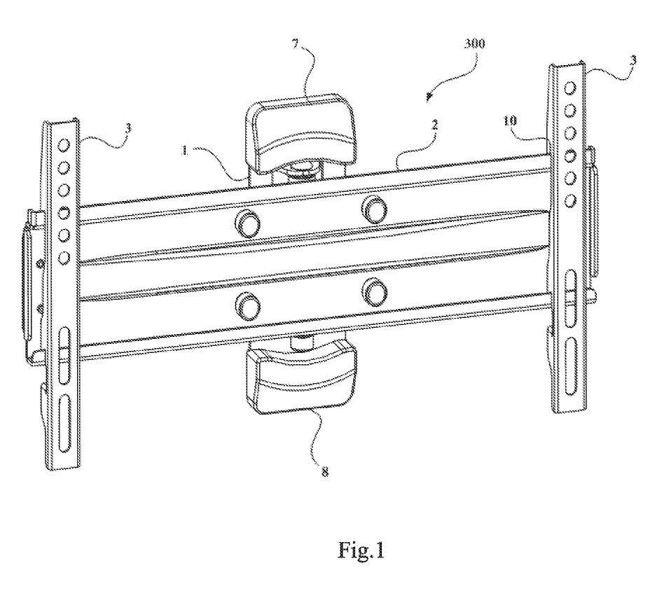

As illustrated in FIG. 1 to FIG. 4, a wall-hang apparatus 300 according to an embodiment of the disclosure includes a base 1, a wall plate 2, and at least one bracket 3, where the base 1 is fixedly connected with a wall 200, the wall plate 2 is hinged with the base 1 through a swivel 4, the swivel 4 is vertically projected onto the wall 200, and the at least one bracket 3 is fixedly connected with the backside of a display device body 100 and is hitched to the wall plate 2.

In an embodiment of the disclosure, the bracket 3 can be fixedly connected with the display device body 100 through screws, and the base 1 can be fixed connected with the wall 200 through screws, and in order to further improve bearing, they can be further connected through expansion screws.

The swivel can be vertically projected onto the wall in the following two cases:

In a first case, the swivel is vertically arranged, and after the display device is attached to the wall, a screen of the display device body swiveled either leftward or rightward remains vertical all the time, that is, the screen is perpendicular to the ground. This structure is applicable to the display device installed at a height slightly different from the height of both eyes of a watcher, e.g., at home, in an office, a meeting room, and other places. In the embodiment as illustrated in FIG. 1 to FIG. 4, the swivel 4 is vertically arranged.

In a second case, the swivel lies in a vertical plane at some angle from the wall, for example, there is an angle of 15 degrees open upward between the swivel and the wall, so that after the display device is attached to the wall, a screen of the display device swiveled either leftward or rightward remains inclined downward. This structure is applicable to the display device installed at a large height, e.g., in an airport, a railway station, a hospital, or other public places, so that it can be watched by a watcher at an appropriate angle.

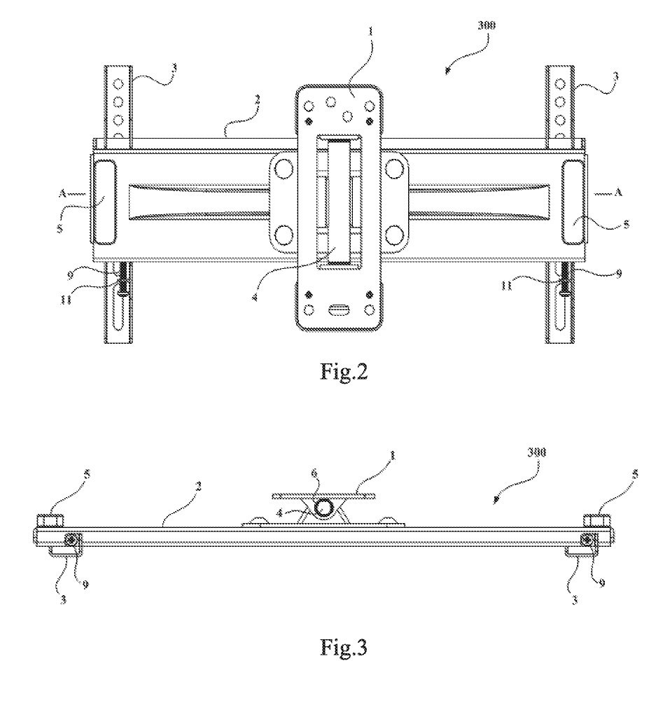

As illustrated in FIG. 2 and FIG. 3, in the optional embodiment, a buffer pad 5 is arranged where the backside of the wall plate 2 contacts the wall. The buffer pad 5 will not be limited to any particular type and shape, although it can be a rubber pad, etc., The buffer pad 5 can be arranged to prevent the display device body and the wall plate 2 being swiveled leftward and rightward from hitting the wall, which would otherwise damage the display device body or the wall.

As illustrated in FIG. 3, in the embodiment of the disclosure, an elastic damper bushing 6 is arranged on the surface of the swivel 4. The elastic damper bushing 6 will not be limited to any particular material, although it can be a rubber bushing, etc. The elastic damper bushing 6 can provide resistance to the wall plate 2 being swiveled relative to the base 1, so that the display device body can maintain any swivel angle. If a line needs to be inserted, or a display angle of the screen of the display device needs to be adjusted, then the display device body can be pushed using a low force so that the display device body is swiveled around the swivel 4.

As illustrated in FIG. 1, the base 1 includes an upper dust-proof cover 7 arranged above the swivel 4, and a lower dust-proof cover 8 arranged below the swivel 4 so that the swivel 4 can be protected from dust and the user can conveniently clean the backside of the display device attached to the wall, and also the display device can be pleasing in appearance and have a good visual effect.

The wall plate 2 and the bracket 3 will not be limited to any particular structure. Since the longer side of a TV set, or another display device is typically arranged transverse, in order to improve bearing by the wall-hang apparatus so that a uniform force is applied to the display device body, optionally the longer side of the wall plate 2 is arranged horizontally, and the number of brackets 3 is at least two, and the longer sides of the brackets 3 are arranged vertically. The number of brackets 3 is typically two, or can be three or more dependent upon the size and the installation of the display device.

As illustrated in FIG. 2, the swivel 4 can be projected onto the wall plate 2 at the center of the wall plate 2, that is, the wall plate 2 is symmetrically installed with respect to the base 1. It shall be noted that in another embodiment of the disclosure, the projection of swivel on the wall can alternatively deviate from the center of the wall plate, that is the wall plate is asymmetrically installed with respect to the base 1, so that after the display device is attached to the wall, the side of the display device body away from the base can be swiveled for a larger room of inserting a line.

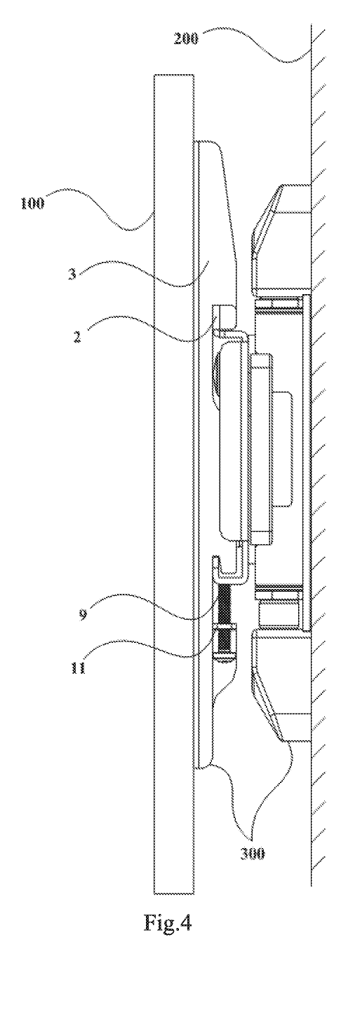

The bracket 3 and the wall plate 2 will not be limited to any particular hitching structure, for example, as illustrated in FIG. 1 and FIG. 4, there are hooks 10 open downward on the bracket 3, and the bracket 3 is hitched to the upper edge of the wall plate 2 through the hooks. Moreover the bracket 3 and the wall plate 2 can alternatively be structured so that there are hooks open upward on the wall plate, and there are holes for hooking on the bracket, so that the bracket is hitched to the hooks of the wall plate through the holes.

As illustrated in FIG. 2 and FIG. 4, there are locking bolts 9, arranged on the bracket 3, which can resist against the bottom of the wall plate 2. Particularly there are bolt installation supports 11 in the bracket 3, and there are threaded through-holes arranged vertically in the bolt installation supports 11, so that the locking bolts 9 are screwed in the threaded through-holes from the bottoms of the bolt installation supports 11. After the bracket 3 fixed to the display device body is attached to the wall plate 2, the locking bolts 9 are screwed, and at this time, the hooks and the locking bolts 9 of the bracket 3 are clamped on the wall plate so that the display device body and the bracket 3 can be prevented from being moved upward and downward, and leftward and rightward relative to the wall plate 2 so as to prevent in effect the display device body and the bracket 3 from falling down, thus enhancing the stability of the display device being installed.

The display device can be attached to the wall through the wall-hang apparatus 300 according to the embodiment of the disclosure in such a way that firstly the base 1 is fixedly installed on the wall 200, then the wall plate 2 is hinged with the base 1 through the swivel 4, next the bracket 3 fixed to the display device body 100 is attached to the wall plate 2, and finally the locking bolts 9 are screwed so that the locking bolts 9 resist against the bottom of the wall plate 2. Alternatively, firstly the wall plate 2 can be hinged with the base 1 through the swivel 4, and then the base 1 can be fixedly installed on the wall 20.

After the display device is installed, the display device body 100 can be swiveled leftward and rightward around the swivel 4 to adjust the swivel angle to thereby provide the operating user with a larger room of conveniently inserting a line while lowering the risk of the display device body falling out of the wall-hang apparatus so as to improve the security and the reliability of the display device being hung on the wall.

Referring to FIG. 4, an embodiment of the disclosure further provides a display device including the display device body 100, and the wall-hang apparatus 300 according to any one of the technical solutions. After the display device is attached to the wall, the user can conveniently insert a line, and also the security and the reliability of the display device being hung on the wall can be improved. Optionally the display device includes a tablet TV set or a tablet display.

Lastly it shall be noted that the foregoing embodiments are merely intended to illustrate but not to limit the technical solutions of the disclosure; and although the disclosure has been described in details with reference to the foregoing embodiments, those ordinarily skilled in the art shall appreciate that the technical solutions recited in the foregoing respective embodiments can be modified or equivalent substitutions can be made to a part of the technical features thereof; and the essence of the corresponding technical solutions will not depart from the spirit and scope of the technical solutions according to the respective embodiments of the disclosure due to these modifications or substitutions.

What is claimed is:

1. A wall-hang apparatus, comprising a base, a wall plate, and at least one bracket, wherein the base is fixedly connected with a wall, the wall plate is hinged with the base through a swivel, the swivel is vertically projected onto the wall, and the at least one bracket is fixedly connected with a backside of a display device body and is hitched to the wall plate.

2. The wall-hang apparatus according to claim 1, wherein the swivel is vertically arranged.

3. The wall-hang apparatus according to claim 1, wherein a buffer pad is arranged where a backside of the wall plate contacts the wall.

4. The wall-hang apparatus according to claim 1, wherein an elastic damper bushing is arranged on a surface of the swivel.

5. The wall-hang apparatus according to claim 1, wherein the base comprises an upper dust-proof cover arranged above the swivel, and a lower dust-proof cover arranged below the swivel.

6. The wall-hang apparatus according to claim 1, wherein a longer side of the wall plate is arranged horizontally, and a longer side of the at least one bracket is arranged vertically.

7. The wall-hang apparatus according to claim 6, wherein the swivel is projected onto the wall plate at the center of the wall plate; or the swivel is projected onto the wall plate in a position deviating from the center of the wall plate.

8. The wall-hang apparatus according to claim 6, wherein locking bolts are arranged on the bracket, which are configured to resist against the bottom of the wall plate.

9. The wall-hang apparatus according to claim 8, wherein there are bolt installation supports in the bracket, and there are threaded through-holes arranged vertically in the bolt installation supports, so that the locking bolts are screwed in the threaded through-holes from the bottoms of the bolt installation supports.

10. The wall-hang apparatus according to claim 6, wherein the number of brackets is at least two.

11. A display device, comprising a display device body, and a wall-hang apparatus comprising a base, a wall plate, and at least one bracket, wherein the base is fixedly connected with a wall, the wall plate is hinged with the base through a swivel, the swivel is vertically projected onto the wall, and the at least one bracket is fixedly connected with a backside of a display device body and is hitched to the wall plate.

12. The display device according to claim 11, wherein the display device comprises a tablet TV set or a tablet display.

13. The display device according to claim 11, wherein the swivel is vertically arranged.

14. The display device according to claim 11, wherein a buffer pad is arranged where a backside of the wall plate contacts the wall.

15. The display device according to claim 11, wherein an elastic damper bushing is arranged on a surface of the swivel.

16. The display device according to claim 11, wherein the base comprises an upper dust-proof cover arranged above the swivel, and a lower dust-proof cover arranged below the swivel.

17. The display device according to claim 11, wherein a longer side of the wall plate is arranged horizontally, and a longer side of the at least one bracket is arranged vertically.

18. The display device according to claim 17, wherein the swivel is projected onto the wall plate at the center of the wall plate; or the swivel is projected onto the wall plate in a position deviating from the center of the wall plate.

19. The display device according to claim 17, wherein locking bolts are arranged on the bracket, which are configured to resist against the bottom of the wall plate.

20. The display device according to claim 19, wherein there are bolt installation supports in the bracket, and there are threaded through-holes arranged vertically in the bolt installation supports, so that the locking bolts are screwed in the threaded through-holes from the bottoms of the bolt installation supports.
